(19) United States
(12) Patent Application Publication
(10) Pub. No.: US 2022/0416103 A1
(43) Pub. Date: Dec. 29, 2022

(54) SEMICONDUCTOR DEVICE AND METHOD OF MANUFACTURING THE SAME

(71) Applicant: NATIONAL INSTITUTE OF ADVANCED INDUSTRIAL SCIENCE AND TECHNOLOGY, Tokyo (JP)

(72) Inventors: Kikuo MAKITA, Ibaraki (JP); Yukiko KAMIKAWA, Ibaraki (JP); Takeyoshi SUGAYA, Ibaraki (JP); Hidenori MIZUNO, Ibaraki (JP)

(21) Appl. No.: 17/780,165

(22) PCT Filed: Sep. 24, 2020
(86) PCT No.: PCT/JP2020/036065

§ 371 Date: May 26, 2022

(30) Foreign Application Priority Data
Nov. 29, 2019 (JP) 2019-216602

(51) Int. Cl. H01L 31/043; H01L 31/05; H01L 31/18

(52) U.S. Cl. CPC H01L 31/043; H01L 31/0512; H01L 31/18

(57) ABSTRACT

Reliability of a semiconductor device is improved. A solar battery includes: a solar battery element SB1 including an interface S1; a solar battery element SB2 including an interface S2 facing the interface S1; and a junction layer 120 being in contact with the interface S1 and the interface S2 and having light transmissivity. In this case, the junction layer 120 includes: a plurality of conductive nanoparticles 105 electrically connecting the solar battery element SB1 and the solar battery element SB2; and an adhesive material 116 filling gaps among the plurality of conductive nanoparticles 105. The interface S1 includes: a flat surface FT having concavity/convexity that is equal to or smaller than 2/3 times the minimum thickness of the junction layer 120; and a concave portion DIT having a depth that is equal to or larger than twice the minimum thickness of the junction layer 120 with respect to the flat surface FT.

### CROSS-REFERENCE TO RELATED APPLICATION

This application is a National Stage application of International Patent Application No. PCT/JP2020/036065, filed on Sep. 24, 2020, which claims priority to Japanese Patent Application No. 2019-216602, filed Nov. 29, 2019, each of which is hereby incorporated by reference in its entirety.

### TECHNICAL FIELD

The present invention relates to a semiconductor device and a method of manufacturing the same, and relates to a technique effectively applied to, for example, a junction layer used in order to stack a plurality of solar cells.

### BACKGROUND

International Patent Publication No. WO/2013/058291 (Patent Document 1) and Non-Patent Document 1 describe a technique related to a mechanical-stack type multi-junction solar battery using junction based on conductive nanoparticles.

Non-Patent Document 2 describes a technique of achieving a photoelectric conversion efficiency of 24.2% by using a multi-junction solar battery to which the junction based on the conductive nanoparticles described in the Non-Patent Document 1 is applied.

International Patent Publication No. WO/2011/024534 (Patent Document 2) describes a technique related to a mechanical-stack type multi-junction solar battery using junction based on an anisotropic conductive junction layer made of conductive microparticles dispersed in a transparent insulating material.

Japanese Patent Application Laid-Open Publication No. 2015-19063 (Patent Document 3) describes a technique related to a mechanical-stack type solar battery using wafer bonding based on an adhesive layer made of an adhesive material and a contact member.

Japanese Patent Application Laid-Open Publication No. 2016-174157 (Patent Document 4) describes a technique related to a multi-junction solar battery using junction based on an adhesive layer containing a conductive carbon component and a binder component.

Patent Document 1: International Patent Publication No. WO/2013/058291

Patent Document 2: International Patent Publication No. WO/2011/024534

Patent Document 3: Japanese Patent Application Laid-Open Publication No. 2015-19063

Patent Document 4: Japanese Patent Application Laid-Open Publication No. 2016-174157

Non-Patent Document 1: H. Mizuno, et al., Japanese Journal of Applied Physics, Vol. 55, (2016), pp. 025001

Non-Patent Document 2: K. Makita et al., 29^{th} European Photovoltaic Solar Energy Conference and Exhibition, (2014), pp. 1427 to 1429

### SUMMARY

It has been studied that, for example, a first semiconductor element and a second semiconductor element made of different semiconductor materials from each other are stacked while being electrically connected. In this case, it is considerable that the first semiconductor element and the second semiconductor element are monolithically stacked by collective crystal growth. However, since the semiconductor material configuring the first semiconductor chip and the semiconductor material configuring the second semiconductor chip are different from each other, this case often causes unmatching in a crystal lattice between the first semiconductor chip and the second semiconductor chip or causes a different crystal structure. Because of this, the monolithic stacking structure of the electrically-connected first semiconductor element and second semiconductor element made of the different semiconductor materials from each other tends to be difficult to provide a favorable junction property.

Accordingly, a technique of joining the first semiconductor element and the second semiconductor element by arranging a plurality of fine conductive nanoparticles between the first semiconductor element and the second semiconductor element is exemplified. This technique is an effective technique since the first semiconductor element and the second semiconductor element causing the lattice unmatching in the monolithic staking case in the crystal growth can be joined regardless of the lattice unmatching. However, the joining property is desirably further improved in order to improve reliability of a semiconductor device.

Other objects and novel characteristics will be apparent from the description of the present specification and the accompanying drawings.

A semiconductor device according to one embodiment includes: a first semiconductor element including a first junction surface; a second semiconductor element including a second junction surface facing the first junction surface; and a junction layer being in contact with the first junction surface and the second junction surface and having light transmissivity. In this case, the junction layer includes: a plurality of conductive nanoparticles electrically connecting the first semiconductor element and the second semiconductor element; and an adhesive material filling gaps among the plurality of conductive nanoparticles. The first junction surface includes a flat surface having concavity/convexity that is equal to or smaller than 2/3 times the minimum thickness of the junction layer, and includes a concave portion having a depth that is equal to or larger than twice the minimum thickness of the junction layer with respect to the flat surface.

A method of manufacturing a semiconductor device according to one embodiment includes: a step (a) of preparing a first semiconductor element having a first junction surface; a step (b) of preparing a second semiconductor element having a second junction surface; and a step (c) of arranging a plurality of conductive nanoparticles on the first junction surface. The method of manufacturing a semiconductor device according to one embodiment further includes: a step (d) of, after the step (c), applying an adhesive material to the first junction surface; and a step (e) of, after the step (d), facing and pressing the second junction surface to the first junction surface through the plurality of conductive nanoparticles and the adhesive material.

According to one embodiment, reliability of a semiconductor device can be improved.

### BRIEF DESCRIPTIONS OF THE DRAWINGS

FIG. 1 is a diagram for explaining an example of application of “smart-stacking technique” to an interface having high flatness;

FIG. 2 is a diagram for explaining an example of application of the “smart-stacking technique” to an interface having low flatness;

FIG. 3 is a cross-sectional view showing a schematic configuration of a multi-junction solar battery according to a first embodiment;

FIG. 4 is a cross-sectional view schematically showing a junction layer;

FIG. 5 is a plan view schematically showing a junction layer formed on a solar battery element;

FIG. 6 is a schematic view enlarging and showing a junction layer sandwiched between a first solar battery element and a second solar battery element;

FIG. 7 is a flowchart showing a flow of steps of manufacturing a multi-junction solar battery;

FIG. 8 is a flowchart showing a flow of a junction step using conductive nanoparticles and an adhesive material;

FIG. 9 is a graph showing a result of a reliability test (temperature cycle test) on the multi-junction solar battery according to the first embodiment;

FIG. 10 is a diagram showing a schematic configuration of a solar battery according to a second embodiment;

FIG. 11(a) is an image obtained by a stereomicroscope observing an interface of a solar battery element made of a silicon cell, and FIG. 11(b) is a graph showing a measurement result of a height profile in a line A-A shown in the image of FIG. 11(a), measured by a laser microscope;

FIG. 12(a) is an observation result of concavity/convexity formed in a micro region of an interface of a solar battery element, observed by an atomic force microscope, and FIG. 12(b) is an observation result of an arrangement state of the conductive nanoparticles in the micro region of the interface of the solar battery element, observed by an atomic force microscope;

FIG. 13 is an outer appearance picture of a solar battery in which a fourth solar battery element is stacked on a third solar battery element through a junction layer made of a plurality of orderly-arranged conductive nanoparticles and an adhesive material filling gaps among the plurality of conductive nanoparticles;

FIG. 14 is a diagram showing a schematic configuration of a solar battery according to a third embodiment; and

FIG. 15 is a graph showing a power generation performance (current-voltage characteristics) of a solar battery according to the third embodiment.

### DETAILED DESCRIPTION

The same components are denoted by the same reference signs in principle throughout all the drawings for describing the embodiments, and the repetitive description thereof will be omitted. Note that hatching may be used even in a plan view so as to make the drawings easy to see.

### First Embodiment

A technical concept of the present first embodiment is widely applicable to a semiconductor device in which a first semiconductor element and a second semiconductor element made of the different semiconductor materials from each other are stacked while being electrically connected. In an exemplified solar battery, this technical concept will be explained below.

<Study of Improvement>

A solar battery is made of a solar battery element converting light energy of sunlight to electrical energy. In this case, the sunlight contains light having various light energies, and light having energy that is equal to or larger than a band gap of the solar battery element can be absorbed by the solar battery element, and be converted to the electrical energy. On the other hand, light having energy that is smaller than the band gap of the solar battery element cannot be absorbed by the solar battery element.

Therefore, in order to improve the photoelectric conversion efficiency of the solar battery, it is important to use various light energies contained in the sunlight. Regarding this, for example, there is a technique of increasing the photoelectric conversion efficiency of the solar battery by stacking a plurality of solar battery elements having different band gaps from one another. In other words, there is a technique of making a multi-junction solar battery by joining a first solar battery element having a large band gap and a second solar battery element having a small band gap. According to this technique, the light having the large light energy in the sunlight is absorbed by the first solar battery element. On the other hand, the light having the small light energy in the sunlight penetrates the first solar battery element, and is absorbed by the second solar battery element. As a result, the multi-junction solar battery can absorb the light having the small light energy in addition to the light having the large light energy in the sunlight, and can convert the light to the electrical energy, and therefore, the photoelectric conversion efficiency can be improved.

In this case, for example, the semiconductor material configuring the first solar battery having the large band gap and the semiconductor material configuring the second solar battery having the small band gap are different from each other, and this case often causes the unmatching in the crystal lattice therebetween or causes the different crystal structure therebetween. Therefore, there is a technique of joining the first solar battery element and the second solar battery element by arranging only a plurality of fine conductive nanoparticles between the first solar battery element and the second solar battery element. In the present specification, this technique is referred to as “smart-stacking technique”. The “smart-stacking technique” is an effective technique since the first solar battery element and the second solar battery element can be joined to each other regardless of the lattice unmatching. In other words, in order to achieve the mechanical-stack type multi-junction solar battery, a junction technique capable of securing the electrical conductivity, the light transmissivity and the mechanical junction strength in the junction layer is necessary. The above-described “smart-stacking technique” can secure the electrical conductivity, the light transmissivity and the mechanical junction strength for, for example, the junction between interfaces having high flatness, the surface roughness (root mean square roughness) of which is about 5 nm.

The present inventors have studied application of the “smart-stacking technique” to the junction between the practically often used interfaces, the surface roughness of which is relatively large. For example, in order to prevent reflection on a surface of a silicon solar battery, the surface does not generally intentionally undergo a mirror finish treatment, and has concavity/convexity of about 1 nm formed in some cases. And, a polycrystalline solar battery (such as “CIGS”) includes a polycrystalline semiconductor layer, and therefore, necessarily has concavity/convexity of about 50 to 100 nm formed at the time of the crystal growth. The present inventors have found that the application of the “smart-stacking technique” to the multi-junction solar battery having the junction surface with such concavity/convexity causes a risk of occurrence of junction peeling due to thermal cycle or others. In other words, the application of the “smart-stacking technique” to the junction of the interface having the relatively large surface roughness has a room for improvement of the securement of the reliability of the junction. This point will be explained in detail below.

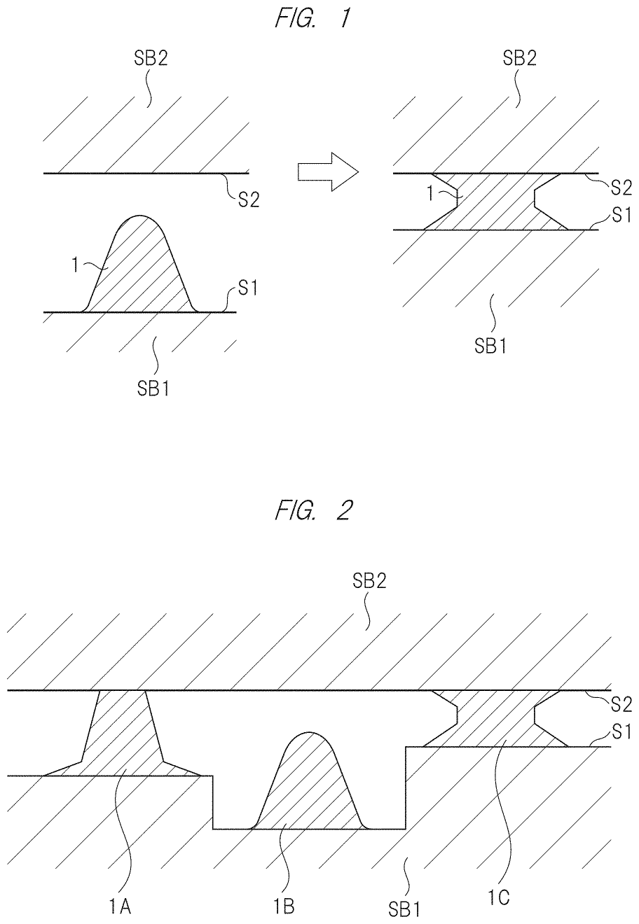

FIG. 1 is a diagram for explaining an example of the application of the “smart-stacking technique” to an interface having high flatness. FIG. 1 shows a configuration in which an interface S1 of a solar battery element SB1 has high flatness while an interface S2 of a solar battery element SB2 has high flatness. In FIG. 1 (left drawing), conductive nanoparticles 1 are arranged on the interface S1 of the solar battery element SB1. On the other hand, the interface S2 of the solar battery element SB2 is arranged to face the interface S1 of the solar battery element SB1. In the “smart-stacking technique”, as shown in FIG. 1 (right drawing), the interface S2 of the solar battery element SB2 is pressed against the interface S1 of the solar battery element SB1 through the conductive nanoparticles 1. In this manner, as shown in FIG. 1 (right drawing), the conductive nanoparticles 1 are compressed, and the interface S1 of the solar battery element SB1 and the interface S2 of the solar battery element SB2 are electrically connected and mechanically joined to each other by the compressed conductive nanoparticles 1. Particularly when the interface S1 of the solar battery element SB1 has high flatness while the interface S2 of the solar battery element SB2 has high flatness as shown in FIG. 1, the interface S1 and the interface S2 are reliably electrically connected and mechanically joined to each other by the compressed conductive nanoparticles 1. In other words, the application of the “smart-stacking technique” to the interface having high flatness can achieve a junction portion excellent in the electrical connection and the mechanical junction.

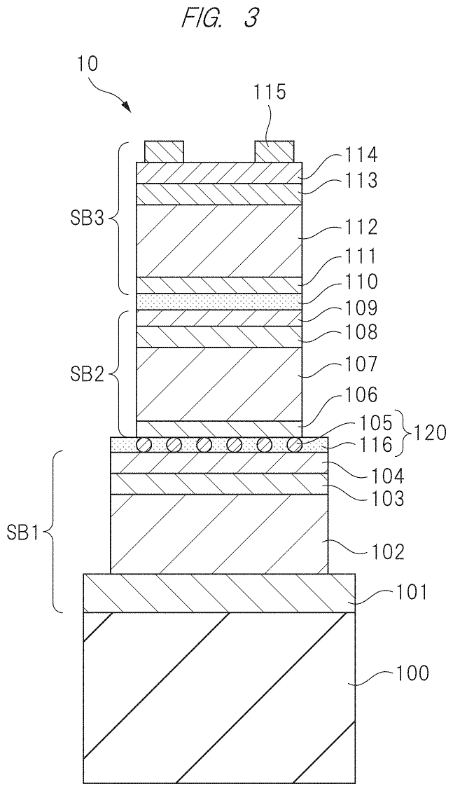

On the other hand, FIG. 2 is a diagram for explaining an example of the application of the “smart-stacking technique” to an interface having low flatness. FIG. 2 shows a configuration in which the interface S1 of the solar battery element SB1 has low flatness while the interface S2 of the solar battery element SB2 has high flatness. In FIG. 2, conductive nanoparticles 1A to 1C are orderly arranged on the interface S1 of the solar battery element SB1. On the other hand, the interface S2 of the solar battery element SB2 is arranged to face the interface S1 of the solar battery element SB1. In the “smart-stacking technique”, as shown in FIG. 2, the interface S2 of the solar battery element SB2 is pressed against the interface S1 of the solar battery element SB1 through the conductive nanoparticles 1A to 1C. In this case, for example, if the flatness of the interface S1 of the solar battery element SB1 is low as shown in FIG. 2, the conductive nanoparticles 1A and 1C are compressed because a distance between the interface S1 and the interface S2 is small. On the other hand, the conductive nanoparticle 1B is not compressed because the distance between the interface S1 and the interface S2 is large. As a result, the interface S1 and the interface S2 are electrically connected and mechanically joined to each other by the compressed conductive nanoparticle 1A and conductive nanoparticle 1C, and the conductive nanoparticle 1B does not contribute to the electrical connection and the mechanical junction between the interface S1 and the interface S2. Therefore, the application of the “smart-stacking technique” to the interface having low flatness as shown in FIG. 2 increases the conductive nanoparticle 1B not compressed, and thus, not contributing to the electrical connection and the mechanical junction between the interface S1 and the interface S2. As a result, when the thermal cycle or others is applied to the junction portion between the solar battery element SB1 and the solar battery element SB2, the junction portion has a high risk of occurrence of the peeling. In other words, for example, the application of the “smart-stacking technique” to the interface having low flatness as shown in FIG. 2 causes a risk of reduction in the reliability of the junction between the solar battery element SB1 and the solar battery element SB2. It is found that the application of the “smart-stacking technique” to the junction of the interface having the relatively large surface roughness has a room for improvement of the securement of the reliability of the junction as described above.

Accordingly, in the present first embodiment, a devisal of the room for the improvement is made. A technical concept of the present first embodiment with this devisal will be explained below.

<Outline Configuration of Multi-Junction Solar Battery>

FIG. 3 is a cross-sectional view showing a schematic configuration of a multi-junction solar battery.

In FIG. 3, a multi-junction solar battery 10 includes the solar battery element SB1 arranged on a soda-lime glass substrate 100, the solar battery element SB2 arranged on this solar battery element SB1, and a solar battery element SB3 arranged on this solar battery element SB2.

First, the solar battery element SB1 includes a back-surface electrode 101 formed on the soda-lime glass substrate 100. This back-surface electrode 101 is made of, for example, a molybdenum (Mo) film. Next, the solar battery element SB1 includes: a light absorbent layer 102 formed on the back-surface electrode 101; a buffer layer 103 formed on the light absorbent layer 102; and a transparent electrode 104 formed on the buffer layer 103. The light absorbent layer 102 is made of a polycrystalline compound semiconductor layer. The light absorbent layer 102 is made of, for example, CuₓIn_{y}Ga_{1-y}Se₂ (referred to as CIGS below). A band gap of the light absorbent layer 102 made of the “CIGS” is, for example, 1.2 eV, and light having light energy that is equal to or larger than 1.2 eV in the sunlight is absorbed by the solar battery element SB1. Subsequently, the buffer layer 103 formed on the light absorbent layer 102 is made of, for example, n-type CdS (cadmium sulfide), and the transparent electrode 104 formed on this buffer layer 103 is made of, for example, ZnO (zinc oxide). The transparent electrode has transmissivity at least for visible light that is a main component of the sunlight. The solar battery element SB1 is configured as described above.

Next, the solar battery element SB2 includes: a p⁺-type AlGaAs layer 106 functioning as a BSF (Back Surface Field) layer; and a p-type GaAs layer 107 functioning as a light absorbent layer formed on the p⁺-type AlGaAs layer 106. Further, the solar battery element SB2 includes: an n-type GaAs layer 108 functioning as a light absorbent layer formed on the p-type GaAs layer 107; and an n⁺-type InGaP layer 109 functioning as a window layer formed on the n-type GaAs layer 108. Therefore, in the solar battery element SB2, a p-n junction is formed at a boundary between the p-type GaAs layer 107 and the n-type GaAs layer 108. A band gap of the solar battery element SB2 is, for example, 1.42 eV, and light having light energy that is equal to or larger than 1.42 eV in the sunlight is absorbed by the solar battery element SB2. The solar battery element SB2 is configured as described above.

Subsequently, the solar battery element SB3 includes: a p⁺-type InAlP layer 111 functioning as a BSF layer; a p-type GaInP layer 112 functioning as a light absorbent layer formed on the p⁺-type InAlP layer 111; an n-type GaInP layer 113 functioning as a light absorbent layer formed on the p-type GaInP layer 112; and an n⁺-type InAlP layer 114 functioning as a window layer formed on the n-type GaInP layer 113. Further, a front-surface electrode 115 is formed on the n⁺-type InAlP layer 114. Therefore, in the solar battery element SB3, a p-n junction is formed at a boundary between the p-type GaInP layer 112 and the n-type GaInP layer 113. A band gap of the solar battery element SB3 is, for example, 1.89 eV, and light having light energy that is equal to or larger than 1.89 eV in the sunlight is absorbed by the solar battery element SB3. The solar battery element SB3 is configured as described above.

In this case, the solar battery element SB2 and the solar battery element SB3 are formed on one semiconductor chip. In other words, the solar battery element SB2 and the solar battery element SB3 are joined and are electrically connected in series to each other by a tunnel junction 110 formed in the semiconductor chip. For example, the tunnel junction 110 is made of a degenerate semiconductor layer sandwiched between the n⁺-type InGaP layer 109 of the solar battery element SB2 and the p⁺-type InAlP layer 111 of the solar battery element SB3. Therefore, the n⁺-type InGaP layer 109 of the solar battery element SB2 and the p⁺-type InAlP layer 111 of the solar battery element SB3 are electrically connected to each other.

On the other hand, the solar battery element SB1 including the polycrystalline compound semiconductor layer is significantly different in a crystal structure from the solar battery element SB2 and the solar battery element SB3, and therefore, is difficult to be formed on one semiconductor chip. In other words, it is difficult to form a junction between the solar battery element SB1 having the polycrystalline structure and the solar battery elements SB2, SB3 having the monocrystalline structure by consecutively growing crystals. This is because, by a method of forming the single crystal (epitaxial growth method), the polycrystalline structure is grown on the polycrystalline structure since the crystals are grown while taking over a crystal structure of a lower portion, and this makes it difficult to form the monocrystalline structure on the polycrystalline structure.

Therefore, the solar battery element SB1 is formed on the first semiconductor chip that is different from the second semiconductor chip on which the solar battery element SB2 and the solar battery element SB3 are formed. As shown in FIG. 3, the first semiconductor chip on which the solar battery element SB1 is formed and the second semiconductor chip on which the solar battery element SB2 and the solar battery element SB3 are formed are joined to each other by, for example, the junction layer 120 containing the plurality of conductive nanoparticles 105 and the adhesive material 116. In this manner, the first semiconductor chip on which the solar battery element SB1 is formed and the second semiconductor chip on which the solar battery element SB2 and the solar battery element SB3 are formed are mechanically joined and electrically connected to each other. For example, as the conductive nanoparticles 105, nanoparticles made of palladium (Pd) may be used.

The junction layer 120 containing the conductive nanoparticles 105 and the adhesive material 116 can provide the junction structure excellent in the electrical conductivity and the light transmissivity. For example, the photoelectric conversion efficiency can be improved when the junction layer 120 containing the conductive nanoparticles 105 and the adhesive material 116 is used for the junction structure of the multi-junction solar battery 10. Particularly by the conductive nanoparticles 105, the transparent electrode can be thinned, and besides, the transparent electrode can be alternatively excluded. Therefore, an optical loss in the transparent electrode can be reduced.

<Configuration of Junction Layer>

Next, the junction layer 120 will be explained.

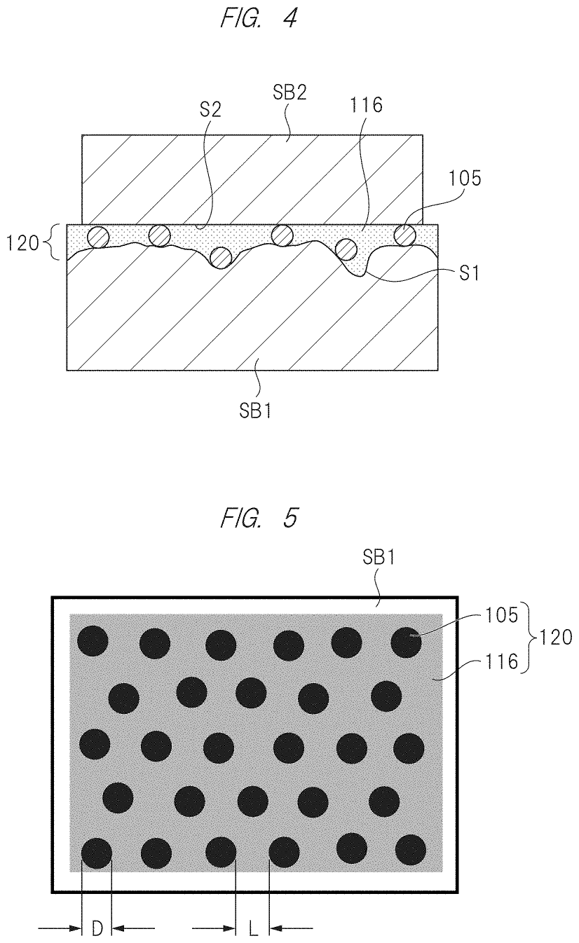

FIG. 4 is a cross-sectional view schematically showing the junction layer 120.

In FIG. 4, the solar battery element SB1 is a solar cell capable of absorbing light having a first wavelength band, and is made of, for example, a polycrystalline cell. On the other hand, the solar battery element SB2 is a solar cell capable of absorbing light having a second wavelength band that is shorter than the first wavelength band, and is made of, for example, a monocrystalline cell. As shown in FIG. 4, the solar battery element SB1 has an interface S1 that is a junction surface while the solar battery element SB2 has an interface S2 that is a junction surface. In this case, a surface roughness of the interface S1 is rougher than a surface roughness of the interface S2, and the junction layer 120 having the light transmissivity is formed to be in contact with both the interfaces S1 and S2.

This junction layer 120 is made to contain the plurality of conductive nanoparticles 105 electrically connecting the solar battery element SB1 and the solar battery element SB2, and the adhesive material 116 filling the gaps among the plurality of conductive nanoparticles 105.

The conductive nanoparticle is made of, for example, any of palladium, gold, silver, platinum, nickel, aluminium, indium, indium oxide, zinc, zinc oxide and copper.

On the other hand, the adhesive material 116 is made of a silicon-based adhesive material or an acrylic adhesive material, and a refractive index of the adhesive material 116 is larger than 1.

The adhesive material 116 desirably has light transmissivity to light having an energy that is larger than the band gap of the semiconductor layer (light absorbent layer 102) included in the solar battery element SB1. This is because, if the adhesive material 116 has the light transmissivity to the light having the energy that is larger than the band gap of the semiconductor layer (light absorbent layer 102) included in the solar battery element SB1 among the light penetrating the solar battery element SB2, this light is not absorbed by the adhesive material 116 and reaches the solar battery element SB1. In other words, this is because, when this light is not absorbed by the adhesive material 116 and reaches the solar battery element SB1, the usage efficiency of the light can be improved since a probability of the absorbance of this light in the semiconductor layer (light absorbent layer 102) of the solar battery element SB1 increases.

Note that the maximum thickness of the adhesive material 116 is desirably equal to or smaller than 100 nm in order to suppress the light loss in the adhesive material 116.

Next, FIG. 5 is a plan view schematically showing the junction layer 120 formed on the solar battery element SB1. As shown in FIG. 5, it is found that the junction layer 120 is made of the plurality of conductive nanoparticles 105 that are orderly arranged, and the adhesive material 116 filling the gaps among the plurality of conductive nanoparticles 105. Since the plurality of conductive nanoparticles 105 are orderly arranged as shown in the drawing, homogeneous electrical connection between the solar battery element SB1 and the solar battery element (SB2) can be achieved by the plurality of conductive nanoparticles 105. In other words, since the plurality of conductive nanoparticles 105 are orderly arranged, local electric-current concentration can be suppressed.

In this case, assuming in FIG. 5 that an average diameter of the conductive nanoparticle 105 is “D” while a distance between the conductive nanoparticles 105 adjacent to each other is “L”, the distance “L” between the conductive nanoparticles 105 adjacent to each other can be designed to be, for example, equal to or larger than twice and equal to or smaller than ten times the average diameter “D” of the conductive nanoparticle 105. Therefore, the electrical conductivity can be secured by the plurality of conductive nanoparticles 105, and the light transmissivity of the junction layer 120 can be also sufficiently secured. In other words, in the present embodiment, since the conductive nanoparticles are orderly arranged to design the distance “L” between the adjacent conductive nanoparticles 105 to be equal to or larger than twice and equal to or smaller than ten times the average diameter “D” of the conductive nanoparticle 105, both the securement of the electrical conductivity and the securement of the light transmissivity in the junction layer 120 can be achieved.

<Operation of Multi-Junction Solar Battery>

The multi-junction solar battery 10 is made as described above, and an operation of the multi-junction solar battery 10 will be explained below with reference to FIG. 3.

First, when the sunlight containing the visible light and the infrared ray is emitted from above the solar battery element SB3 in FIG. 3, the sunlight is emitted to the n⁺-type InAlP layer 114 that is the component of the solar battery element SB3. In this case, the n⁺-type InAlP layer 114 functions as the window layer, and has the light transmissivity to at least the visible light and the infrared ray that are the main components of the sunlight. Therefore, the sunlight penetrates the n⁺-type InAlP layer 114. Next, the sunlight having penetrated the n⁺-type InAlP layer 114 enters the solar battery element SB3 positioned in a lower layer of the n⁺-type InAlP layer 114. Specifically, the sunlight is emitted to the n-type GaInP layer 113, the p-n junction portion formed in the boundary region between the n-type GaInP layer 113 and the p-type GaInP layer 112, and the p-type GaInP layer 112. In this case, each of the n-type GaInP layer 113 and the p-type GaInP layer 112 has the band gap of 1.89 eV, and therefore, absorbs the light having the energy that is equal to or larger than 1.89 eV in the sunlight. Specifically, electron(s) existing in a valance band of the GaInP layer (the n-type GaInP layer 113 and the p-type GaInP layer 112) receives the light energy supplied from the sunlight, and is excited to a conduction band. Therefore, the electron(s) is accumulated in the conduction band, and a positive hole is formed in the valance band. In this manner, at the time of the emission of the sunlight to the solar battery element SB3, by the light having the light energy that is equal to or larger than 1.89 eV contained in the sunlight, the electron(s) is excited to the conduction band of the GaInP layer, and the positive hole is formed in the valance band of the GaInP layer. The energy of the conduction band of the n-type GaInP layer 113 configuring either one of the p-n junction is positioned to be lower in terms of electron than that of the conduction band of the p-type GaInP layer 112 configuring the other of the p-n junction. Therefore, the electron(s) excited to the conduction band moves to the n-type GaInP layer 113, and the electron(s) is accumulated in the n-type GaInP layer 113. On the other hand, the positive hole existing in the valance band moves to the p-type GaInP layer 112, and the positive hole is accumulated in the p-type GaInP layer 112. As a result, electromotive force (V3) is generated between the p-type GaInP layer 112 and the n-type GaInP layer 113.

Meanwhile, the light having the energy that is smaller than 1.89 eV in the sunlight is not absorbed by the GaInP layer, and penetrates the GaInP layer. Therefore, in FIG. 3, the light having the energy that is smaller than 1.89 eV in the sunlight enters the solar battery element SB2 positioned in a lower layer of the solar battery element SB3. Specifically, the light having the energy that is smaller than 1.89 eV in the sunlight is emitted through the n⁺-type InGaP layer 109 functioning as the window layer to the n-type GaAs layer 108, the p-n junction formed in the boundary region between the n-type GaAs layer 108 and the p-type GaAs layer 107, and the p-type GaAs layer 107. In this case, each of the n-type GaAs layer 108 and the p-type GaAs layer 107 has the band gap of 1.42 eV, and therefore, absorbs the light having the energy that is smaller than 1.89 eV and equal to or larger than 1.42 eV in the sunlight. Specifically, electron(s) existing in a valance band of the GaAs layer (the n-type GaAs layer 108 and the p-type GaAs layer 107) receives the light energy supplied from the sunlight, and is excited to a conduction band. Therefore, the electron(s) is accumulated in the conduction band, and a positive hole is formed in the valance band. In this manner, at the time of the emission of the sunlight to the solar battery element SB2, by the light having the light energy that is smaller than 1.89 eV and equal to or larger than 1.42 eV, the electron(s) is excited to the conduction band of the GaAs layer, and the positive hole is formed in the valance band of the GaAs layer. The energy of the conduction band of the n-type GaAs layer 108 configuring either one of the p-n junction is positioned to be lower in terms of electron than that of the conduction band of the p-type GaAs layer 107 configuring the other of the p-n junction. Therefore, the electron(s) excited to the conduction band moves to the n-type GaAs layer 108, and the electron(s) is accumulated in the n-type GaAs layer 108. On the other hand, the positive hole existing in the valance band moves to the p-type GaAs layer 107, and the positive hole is accumulated in the p-type GaAs layer 107. As a result, electromotive force (V2) is generated between the p-type GaAs layer 107 and the n-type GaAs layer 108.

Meanwhile, the light having the light energy that is smaller than 1.42 eV in the sunlight is not absorbed by the GaAs layer, and penetrates the GaAs layer. Therefore, in FIG. 3, the light having the light energy that is smaller than 1.42 eV in the sunlight is emitted through the junction layer 120 containing the conductive nanoparticles 105 and the adhesive material 116 to the solar battery element SB1 positioned in a lower layer of the solar battery element SB2. Specifically, the light having the light energy that is smaller than 1.42 eV in the sunlight is emitted through the transparent electrode 104 to the buffer layer 103 and the light absorbent layer 102. In this case, the light absorbent layer 102 has the band gap of 1.2 eV, and therefore, absorbs the light having the light energy that is smaller than 1.42 eV and equal to or larger than 1.2 eV in the sunlight. Specifically, electron(s) existing in a valance band of the light absorbent layer 102 receives the light energy supplied from the sunlight, and is excited to a conduction band. Therefore, the electron(s) is accumulated in the conduction band, and a positive hole is formed in the valance band. In this manner, at the time of the emission of the sunlight to the solar battery element SB1, by the light having the light energy that is smaller than 1.42 eV and equal to or larger than 1.2 eV, the electron(s) is excited to the conduction band of the light absorbent layer 102, and the positive hole is formed in the valance band of the light absorbent layer 102. As a result, while the positive hole is accumulated in the light absorbent layer 102, the electron(s) existing in the conduction band is accumulated in the buffer layer 103. As a result, electromotive force (V1) is generated between the light absorbent layer 102 and the buffer layer 103.

Note that a surface of the “CIGS” can be converted to be of n-type in accordance with conditions for the film formation of the light absorbent layer 102 made of the “CIGS”. In this case, the electromotive force (V1) is generated between a surface layer (n-type layer) of the light absorbent layer 102 and an internal layer (p-type layer) of the light absorbent layer.

In this case, the solar battery element SB1 and the solar battery element SB2 are connected in series by the plurality of conductive nanoparticles 105, and the solar battery element SB2 and the solar battery element SB3 are connected in series by the tunnel junction 110. In other words, the solar battery element SB1, the solar battery element SB2 and the solar battery element SB3 are connected in series. As a result, electromotive force that is combination of the electromotive force (V1), the electromotive force (V2) and the electromotive force (V3) is generated in the multi-junction solar battery 10 made of the series-connected solar battery element SB1, solar battery element SB2 and solar battery element SB3. And, for example, when a load is connected between the front-surface electrode 115 and the back-surface electrode 101, the electrons flow from the front-surface electrode 115 through the load to the back-surface electrode 101. In other words, the electric current flows from the back-surface electrode 101 through the load to the front-surface electrode 115. By the operation of the multi-junction solar battery 10 as described above, the load can be driven.

As described above, the multi-junction solar battery 10 can also absorb the light having the small light energy in addition to the light having the large light energy contained in the sunlight, and can convert the light into the electrical energy, and therefore, the photoelectric conversion efficiency can be improved. In other words, the multi-junction solar battery 10 can utilize even the light having the small light energy that cannot be utilized in a single solar battery, and therefore, is excellent in the improvement of the use efficiency of the sunlight.

<Characteristics of First Embodiment>

Subsequently, characteristics of the present first embodiment will be explained.

As shown in FIG. 3, as the characteristics of the present first embodiment, for example, the first semiconductor chip on which the solar battery element SB1 is formed and the second semiconductor chip on which the solar battery element SB2 and the solar battery element SB3 are formed are joined to each other by the junction layer 120 containing the plurality of nanoparticles 105 and the adhesive material 116. In this manner, the present first embodiment can improve the reliability of the junction between the first semiconductor chip and the second semiconductor chip.

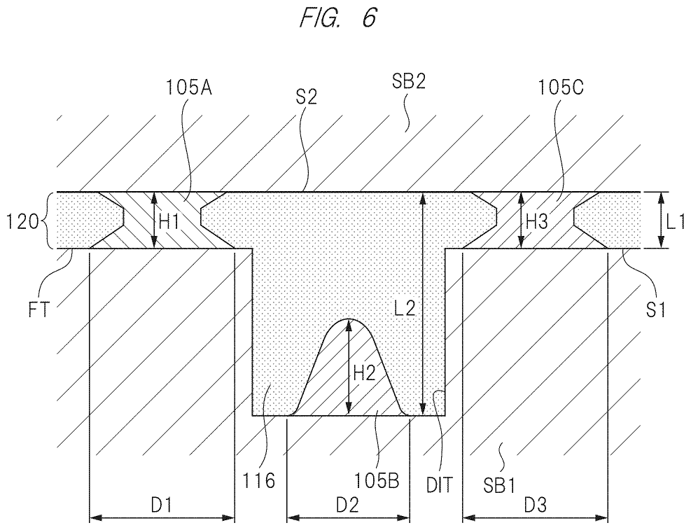

FIG. 6 is a schematic view enlarging and showing the junction layer 120 sandwiched between the solar battery element SB1 and the solar battery element SB2. In FIG. 6, a surface roughness (root mean square roughness) of the interface S1 of the solar battery element SB1 is rougher than that of the interface S2 of the solar battery element SB2. The surface roughness of the interface S1 of the solar battery element SB1 is rough, and the interface S1 includes, for example, a flat surface FT and a concave portion DIT. In this case, assuming that the minimum thickness of the junction layer 120 is “L1”, the concavity/convexity of the flat surface FT is equal to or smaller than 2/3 of the minimum thickness “L1” of the junction layer 120, and the flat surface FT is illustrated with a straight line in FIG. 6. In one example, the surface roughness of the concavity/convexity of the flat surface FT is equal to or smaller than 100 nm. The concave portion DIT has a depth that is equal to or larger than twice the minimum thickness “L1” of the junction layer 120 with respect to the flat portion FT. If the concave portion DIT has a further depth that is equal to or larger than three times to five times the minimum thickness “L1”, circumstances to be overcome are more significant. In this manner, the interface S1 is made of combination of the flat portion FT and the concave portion DIT. In this case, the minimum thickness “L1” of the junction layer 120 formed between the interface S1 and the interface S2 is a distance between the flat portion FT of the interface S1 and the interface S2. On the other hand, the maximum thickness “L2” of the junction layer 120 formed between the interface S1 and the interface S2 is a distance between a base of the concave portion DIT of the interface S1 and the interface S2.

Meanwhile, the surface roughness of the interface S2 of the solar battery element SB2 is about 5 nm, and the flatness of the interface S2 is high. Therefore, in FIG. 6, the interface S2 is illustrated with a straight line. The concavity/convexity of the interface S2 is equal to or smaller than 2/3 of the minimum thickness “L1” of the junction layer 120.

A precondition for the present first embodiment is the formation of the junction layer 120 as shown in FIG. 6. In this case, for example, the conductive nanoparticle 105A arranged on the flat portion FT of the interface S1 is sandwiched and is compressed by the interface S1 and the interface S2. As a result, the conductive nanoparticle 105A interposes between the flat portion FT of the interface S1 and the interface S2, and contributes to the electrical connection between the interface S1 and the interface S2. An average diameter “D1” of this conductive nanoparticle 105A is, for example, equal to or larger than 10 nm and equal to or smaller than 200 nm, and an average height “H1” of this conductive nanoparticle 105A is, for example, equal to or larger than 2.5 nm and equal to or smaller than 100 nm.

In this specification, as shown in FIG. 6, the average diameter is an average of diameters of the conductive nanoparticles observed in plan view viewed from an upper surface of the interface S1, and the average height is an average of heights of the conductive nanoparticles observed in cross-sectional view of the junction layer after the formation of the junction layer.

Similarly, the conductive nanoparticle 105C arranged on the flat portion FT of the interface S1 is sandwiched and compressed by the interface S1 and the interface S2. As a result, the conductive nanoparticle 105C interposes between the flat portion FT of the interface S1 and the interface S2, and contributes to the electrical connection between the interface S1 and the interface S2. An average diameter “D3” of this conductive nanoparticle 105C is, for example, equal to or larger than 10 nm and equal to or smaller than 200 nm, and an average height “H3” of this conductive nanoparticle 105C is, for example, equal to or larger than 2.5 nm and equal to or smaller than 100 nm.

On the other hand, the conductive nanoparticle 105B arranged on the base of the concave portion DIT of the interface S1 is not compressed between the interface S1 and the interface S2. This is because the distance “L2” between the concave portion DIT of the interface S1 and the interface S2 is larger than an average height “H2” of the conductive nanoparticle 105B. As a result, the conductive nanoparticle 105B interposes between the concave portion DIT of the interface S1 and the interface S2, but does not contribute to the electrical connection between the interface S1 and the interface S2. An average diameter “D2” of this conductive nanoparticle 105B is, for example, equal to or larger than 10 nm and equal to or smaller than 200 nm, but the average height “H2” of this conductive nanoparticle 105B is larger than the average height “H1” of the conductive nanoparticle 105A and the average height “H3” of the conductive nanoparticle 105C because the conductive nanoparticle 105B is not compressed.

As described above, in the present first embodiment, since the interface S1 is made of the flat portion FT and the concave portion DIT, the plurality of conductive nanoparticles 105 interposing between the interface S1 and the interface S2 are the mixture of the conductive nanoparticles (105A and 105C) contributing to the electrical connection between the interface S1 and the interface S2 and the conductive nanoparticle (105B) not contributing to the electrical connection between the interface S1 and the interface S2. In other words, in the present embodiment, the plurality of conductive nanoparticles 105 interposing between the interface S1 and the interface S2 include the conductive nanoparticles having different shapes from one another. Specifically, the average heights (“H1” and “H3”) of the compressed conductive nanoparticles (105A and 105C) contributing to the electrical connection between the interface S1 and the interface S2 are smaller than the average height (“H2”) of the not-compressed conductive nanoparticle (105B) not contributing to the electrical connection between the interface S1 and the interface S2.

Therefore, for example, if the junction layer 120 is made of only the conductive nanoparticles 105, the electrical connection and the mechanical junction between the interface S1 and the interface S2 are achieved by the compressed conductive nanoparticle 105A and the compressed conductive nanoparticle 105C while the electrical connection and the mechanical junction between the interface S1 and the interface S2 are not achieved by the not-compressed conductive nanoparticle 105B as shown in FIG. 6. Therefore, when the interface S1 is made of the flat portion FT and the concave portion DIT, if the junction layer 120 is made of only the conductive nanoparticles 105, the not-compressed conductive nanoparticle 105B is caused, which results in a risk of weakening the mechanical junction between the interface S1 and the interface S2. In other words, the application of the “smart-stacking technique” to the interface S1 having the low flatness increases an amount of the not-compressed conductive nanoparticle 105B not contributing to the electrical connection and the mechanical junction between the interface S1 and the interface S2. As a result, the application of the thermal cycle or others to the junction layer 120 between the solar battery element SB1 and the solar battery element SB2 increases the risk of the peeling of this junction layer 120. In other words, the application of the “smart-stacking technique” to the interface S1 having the low flatness causes the risk of the reduction in the reliability of the junction between the solar battery element SB1 and the solar battery element SB2. Therefore, the application of the “smart-stacking technique” to the interface S1 having the relatively large surface roughness has a room for the improvement in order to secure the reliability of the junction.

Regarding this point, in the present embodiment, for example, as shown in FIG. 6, not only the “smart-stacking technique” of making the junction layer 120 by using only the conductive nanoparticles 105 but also the adhesive material 116 filling the gaps among the conductive nanoparticles 105 are provided. In this manner, according to the present first embodiment, as shown in FIG. 6, in addition to the mechanical junction by the compressed conductive nanoparticles (105A and 105C), the mechanical junction between the interface S1 and the interface S2 can be also achieved by the adhesive material 116 covering the not-compressed conductive nanoparticle 105B. In other words, since the junction layer 120 is provided with the adhesive material 116, the present first embodiment can compensate the reduction in the reliability of the junction between the interface S1 and the interface S2 due to the increase in the amount of the not-compressed conductive nanoparticle 105B on the interface S1 having the large surface roughness.

According to the characteristic point of the present first embodiment as described above, even if there is the interface S1 having the large surface roughness, the strength of the mechanical junction between the interface S1 and the interface S2 can be improved by the junction layer 120 because of synergetic effect of the mechanical junction based on the compressed conductive nanoparticles (105A and 105C) and the mechanical junction based on the adhesive material 116. As a result, according to the present first embodiment, even if the thermal cycle or others is applied to the junction layer 120 between the solar battery element SB1 and the solar battery element SB2, the risk of the peeling of this junction layer 120 can be reduced. In other words, the application of the characteristic point of the present first embodiment to the interface S1 having the low flatness can improve the reliability of the junction between the interface S1 and the interface S2.

Further, since the plurality of conductive nanoparticles 105 are arranged in the junction layer 120 while the adhesive material 116 is arranged to fill the gaps among the plurality of conductive nanoparticles 105, the present first embodiment can improve the strength of the mechanical junction of the junction layer 120, and besides, provide an advantage of the reduction in the light reflection loss in the junction layer 120. This is because the “smart-stacking technique” of arranging only the plurality of conductive nanoparticles 105 in the junction layer 120 causes the air gaps among the plurality of conductive nanoparticles 105, the air gap being made of air having a refractive index of 1, while the present first embodiment makes the arrangement of the adhesive material 116 having a larger refractive index than 1 to fill the gaps among the plurality of conductive nanoparticles 105. In other words, this is because difference in the refractive index between the junction layer 120 and the solar battery element SB1 or the solar battery element SB2 adjacent to the junction layer 120 is small, which results in the reduction of the reflection in the junction layer 120, since the junction layer 120 of the present embodiment contains the adhesive material 116 having the larger refractive index than 1 in place of the air having the refractive index of 1.

Therefore, according to the characteristic point of the preset first embodiment, by the junction layer 120 containing the conductive nanoparticles 105 and the adhesive material 116, the strength of the mechanical junction between the interface S2 and the interface S1 having the low flatness can be improved without the increase in the light reflection loss in the junction layer 120. In other words, the characteristic point of the preset first embodiment provides the significant effect capable of improving the junction reliability of the multi-junction solar battery without the reduction in the performance of the multi-junction solar battery.

In the present first embodiment, note that the junction layer 120 joining the interface S1 having the large surface roughness and the interface S2 having the high flatness has been exemplified for the explanation. However, the technical concept of the present first embodiment is not limited to this example. The technical concept is also variously applicable to, for example, a junction layer joining an interface S1 having high flatness and an interface S2 having large surface roughness and a junction layer joining an interface S1 and an interface S2 both having large surface roughness.

Further, the adhesive material 116 contained in the junction layer 120 can be made of a conductive adhesive material having light transmissivity. In this case, not only the compressed conductive nanoparticles 105 in contact with both the interface S1 and the interface S2 but also the adhesive material 116 interposing between the interface S1 and the interface S2 contribute to the electrical connection between the solar battery element SB1 and the solar battery element SB2. Therefore, since the adhesive material 116 having the light transmissivity contained in the junction layer 120 is made of the conductive adhesive material, the present first embodiment can improve the reliability of the electrical connection between the solar battery element SB1 and the solar battery element SB2 stacked to sandwich the junction layer 120 therebetween while securing the light transmissivity.

<Method of Manufacturing Multi-Junction Solar Battery>

Subsequently, a method of manufacturing the multi-junction solar battery 10 will be explained with reference to the drawings.

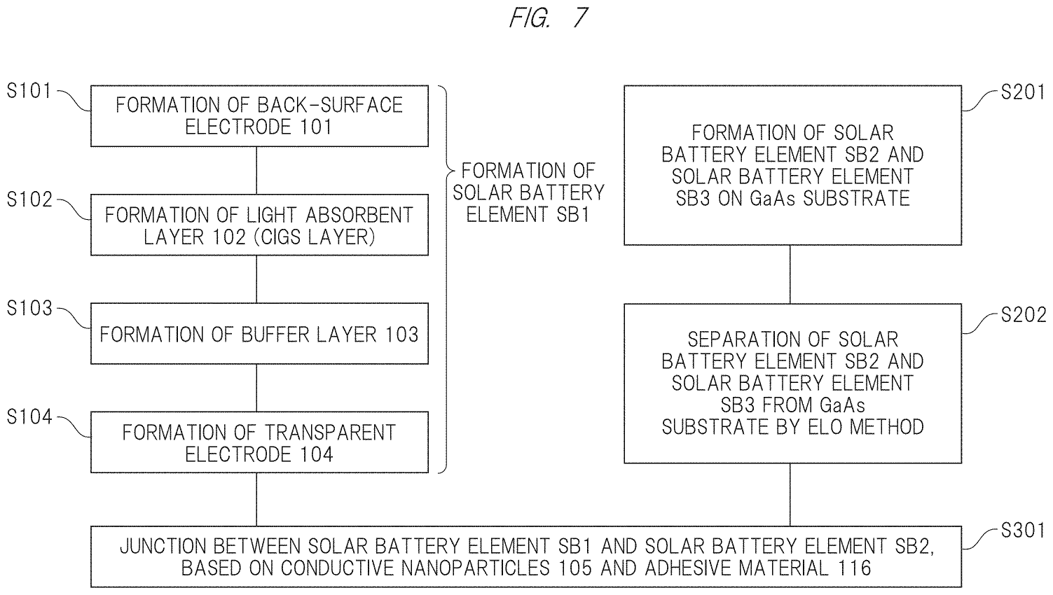

FIG. 7 is a flowchart showing a flow of the manufacturing steps of the multi-junction solar battery 10.

In FIG. 7, a step of forming the solar battery element SB1 will be explained. The soda-lime glass substrate 100, a surface of which has been rinsed, is prepared first, and then, the back-surface electrode 101 is formed on the surface of this soda-lime glass substrate 100 (S101). The back-surface electrode 101 can be made of, for example, a molybdenum film (Mo film) by using, for example, a sputtering method. Next, the light absorbent layer 102 is formed on the back-surface electrode 101 (S102). The light absorbent layer 102 can be made of, for example, the polycrystalline compound semiconductor layer made of “CIGS” by using, for example, a vacuum deposition method. Then, the buffer layer 103 is formed on the light absorbent layer 102 (S103). The buffer layer 103 can be made of, for example, an n-type CdS by using, for example, a chemical solution (bath) deposition method.

In the chemical solution deposition method, note that the CdS is formed by, for example, pouring aqueous solution of ammonia (NH₃), cadmium sulfate (CdSO₄) and thiourea (CSN₂H₄) into a beaker, and then, putting the beaker into a water bath maintained at 80° C. while immersing the surface of the light absorbent layer 102 into this aqueous solution, and maintaining the aqueous solution for 16 minutes in total to be gradually warmed from a room temperature.

Then, the transparent electrode 104 is formed on the buffer layer 103 (S104). The transparent electrode 104 can be made of, for example, zinc oxide.

The concavity/convexity surface is generally formed on the surface of the polycrystalline compound semiconductor layer made of the “CIGS” since the layer is made of the polycrystal. After the buffer layer 103 and the transparent electrode 104 are formed on the polycrystalline compound semiconductor layer made of the “CIGS”, the concavity/convexity of the surface slightly becomes gentle, but is significantly larger than the sizes of the conductive nanoparticles. Therefore, a step of wet etching on the surface of the polycrystalline compound semiconductor layer made of the “CIGS” or a step of flattening the surface of the transparent electrode 104 by a CMP polishing (see the [Non-Patent Document 2]) may be added. However, even when such a flattening step is added, the concave portion not contributing to the junction based on the conductive nanoparticles remains.

The solar battery element SB1 can be formed as described above.

Next, in FIG. 7, a step of forming the stacking structure of the solar battery element SB2 and the solar battery element SB3 will be explained. First, by using a general process, the stacking structure of the solar battery element SB2 and the solar battery element SB3 is formed on the GaAs substrate, a surface of which has been rinsed (S201). The stacking structure can be formed by using, for example, a crystal growth method such as a metal organic chemical vapor deposition (MOCVD) method. Then, by using an ELO (Epitaxial lift off) method, the stacking structure of the solar battery element SB2 and the solar battery element SB3 is separated from the GaAs substrate (S202). In this manner, the stacking structure of the solar battery element SB2 and the solar battery element SB3 can be formed. The interface S2 serving as the junction surface is formed on the solar battery element SB2 as described above, and is secured to have the flatness suitable for the junction based on the conductive nanoparticles because of being the surface separated from the GaAs substrate by the ELO method.

Subsequently, in FIG. 7, a step of joining the solar battery element SB1 and the solar battery element SB2 will be explained. The solar battery element SB1 and the solar battery element SB2 are joined to each other by, for example, using the plurality of conductive nanoparticles 105 and the adhesive material 116 (S301).

In this manner, the solar battery element SB1 and the solar battery element SB2 are mechanically joined and electrically connected to each other.

As described above, the multi-junction solar battery 10 can be manufactured.

<<Step for Junction Based on Conductive Nanoparticles and Adhesive Material>>

The step for the junction based on the conductive nanoparticles and the adhesive material will be explained in detail below.

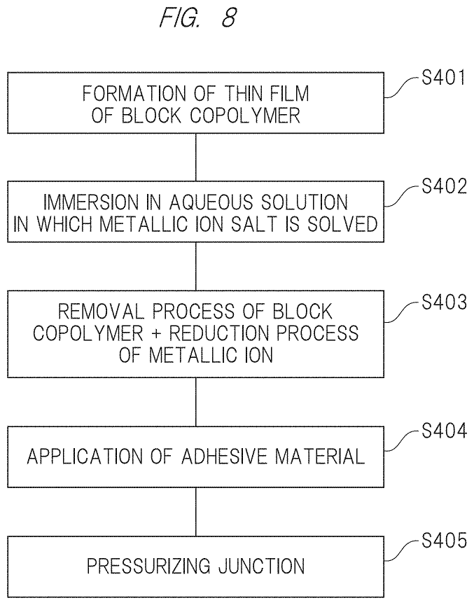

FIG. 8 is a flowchart showing a flow of the junction step using the conductive nanoparticles and the adhesive material. First, a thin film made of a block copolymer is formed on the surface of the solar battery element SB1 (the surface of the transparent electrode 104) serving as one member of the junction target (S401). Specifically, the block copolymer made of polystyrene that is a hydrophobic moiety solved in an organic solvent such as toluene or ortho-xylene and poly-2-vinyl pyridine that is a hydrophilic moiety is applied onto the surface of the transparent electrode 104 by a spin coating method or a dip coating method. In this manner, a poly-2-vinyl pyridine block is patterned on the surface of the transparent electrode 104 because of phase separation of the block copolymer. In other words, a hydrophilic domain region is formed on the surface of the transparent electrode 104. Next, the solar battery element SB1 is immersed in aqueous solution in which a metallic ion salt represented by Na₂PdCl₄ is solved (S402). In this manner, a metallic ion (Pd²⁺) can be introduced into the pattern made of the poly-2-vinyl pyridine block by chemical interaction with the pyridine. In other words, the metallic ion (Pd²⁺) is selectively precipitated in the above-described hydrophilic domain region. Then, after sufficient rinsing, a removal process of the block copolymer and a reduction process of the metallic ion are performed to the solar battery element SB1 by using, for example, argon plasma or others (S403). As a result, the orderly-arranged conductive nanoparticles 105 with the pattern can be formed. Next, by a spinner apparatus, the adhesive material 116 is applied onto the interface S1 of the solar battery element SB1 on which the orderly-arranged conductive nanoparticles 105 are formed (S404). Then, the solar battery element SB2 serving as the other member of the junction target is overlapped on the solar battery element SB1 on which the conductive nanoparticles 105 are arranged and on which the adhesive material 116 is applied, and then, an appropriate pressurizing process (for example, at 5 N/cm²) is performed thereto, and therefore, the solar battery element SB1 and the solar battery element SB2 are joined to each other (S405). In this manner, the junction using the conductive nanoparticles 105 and the adhesive material 116 between the solar battery element SB1 and the solar battery element SB2 is achieved.

In a specific trial production, a silicon-based adhesive material (Silicone Pressure Sensitive Adhesive X-40-3306 (very low adhesion-type) produced by Shin-Etsu (Silicon) Chemical., Ltd.) that is one type of the adhesive material was used as the adhesive material 116 although not particularly limited. A hardening (solidifying) step for the adhesive material is unnecessary, and the solar battery element SB1 and the solar battery element SB2 can be joined to each other by the pressuring process (for example, at 5 N/cm²) at a room temperature in the step S405. In the step S404, the adhesive material is diluted by toluene solvent for the spinner coating that thinly applies the adhesive material. However, the toluene solvent may be volatilized after the coating and before the pressurizing junction step (that is the step S405).

As a method of forming the orderly-arranged conductive nanoparticles 105, not only the above-described self-assembly method using the block copolymer but also a microcontact stamp method using a stamp having a shape pattern are exemplified. In the microcontact stamp method, a micro concavity/convexity shape is formed first on a stamp surface of a stamp made of polydimethylsiloxane (PDMS). This concavity/convexity shape is achieved by, for example, combination of an electron-beam lithography or a photolithography technique and an etching technique. Then, a metal such as silver (Ag) is deposited on the micro-concavity/convexity shaped stamp surface by, for example, a vapor deposition method or a sputtering method. In this state, when a convex portion of the stamp is brought in contact with the interface S1 of the solar battery element SB1, the desirable orderly-arranged pattern of the conductive nanoparticles 105 can be formed on the interface S1 of the solar battery element SB1.

In the self-assembly method using the block copolymer, the size of the conductive nanoparticle 105 is, for example, equal to or larger than 10 nm and equal to or smaller than 200 nm because of limitation of this manufacturing method.

On the other hand, in the stamp method, the size of the conductive nanoparticle 105 is, for example, equal to or larger than 100 nm and equal to or smaller than 500 nm because of forming limitation (lower limitation) of the micro concavity/convexity shape.

<Characteristics of Manufacturing of First Embodiment>

Subsequently, characteristics points of the manufacturing of the multi-junction solar battery of the present first embodiment will be explained.

A first characteristic point of the manufacturing of the present first embodiment is that the adhesive material 116 is applied onto the interface S1 including the plurality of arranged conductive nanoparticles 105 after the plurality of conductive nanoparticles 105 are arranged on the interface S1 of the solar battery element SB1. In other words, the first characteristic point of the manufacturing of the present first embodiment is that, on the precondition that the step of arranging the plurality of conductive nanoparticles 105 and the step of applying the adhesive material 116 are separately performed, the step of applying the adhesive material 116 is performed after the step of arranging the plurality of conductive nanoparticles 105.

In this manner, the plurality of orderly-arranged conductive nanoparticles 105 can be formed, and then, the adhesive material 116 can be applied without the disorder of the orderly-arranged conductive nanoparticles 105. As a result, according to the present first embodiment, the homogeneity of the electric current flowing in the junction layer 120 can be improved by the orderly-arranged conductive nanoparticles 105. In other words, the local electric-current concentration of the electric current flowing in the junction layer 120 can be suppressed.

For example, in order to simplify the manufacturing steps, the method of applying the adhesive material 116 containing the conductive nanoparticles 105 dispersed in the adhesive material 116 is also considerable. However, this method cannot orderly arrange the conductive nanoparticles 105. Therefore, this method causes the possibility of the occurrence of the local electric-current concentration of the electric current flowing in the junction layer 120 since the conductive nanoparticles are randomly arranged.

On the other hand, according to the first characteristic point of the manufacturing of the present first embodiment, the method of dispersing and applying the conductive nanoparticles 105 in the adhesive material 116 is not applied. Therefore, the conductive nanoparticles 105 can be formed to be orderly arranged, and then, the adhesive material 116 can be applied without the disorder of the plurality of orderly-arranged conductive nanoparticles 105. As a result, according to the present first embodiment, the homogeneity of the electric current flowing in the junction layer 120 can be improved by the orderly-arranged conductive nanoparticles 105.

Next, a second characteristic point of the manufacturing of the present first embodiment is that the pressing step of pressing the interface S2 of the solar battery element SB2 to face the interface S1 of the solar battery element SB1 through the plurality of conductive nanoparticles 105 and the adhesive material 116 can be performed with heating, or can be performed at an atmospheric temperature (room temperature) without the heating. In this manner, for example, by the pressing step at the atmospheric temperature (room temperature) without the heating, the manufacturing steps can be simplified.

For examples, when a part of an element configuring the conductive nanoparticles 105 is dispersed in the solar battery element SB1 and the solar battery element SB2, ohmic contact between the solar battery element SB1 and the junction layer 120 containing the conductive nanoparticles 105 and ohmic contact between the solar battery element SB2 and the junction layer 120 containing the conductive nanoparticles 105 are formed to reduce the junction resistance. In this case, when the pressing step is performed with the heating, the part of the element configuring the conductive nanoparticles 105 is easily dispersed in the solar battery element SB1 and the solar battery element SB2. Therefore, the pressing step is desirable to be performed with the heating in order to easily disperse the part of the element configuring the conductive nanoparticles 105 in the solar battery element SB1 and the solar battery element SB2.

However, if the element configuring the conductive nanoparticles 105 is, for example, palladium (Pd), the palladium is sufficiently dispersed in the solar battery element SB1 and the solar battery element SB2 even when the pressing step is performed at the atmospheric temperature without the heating. Therefore, the pressing step can be performed at the atmospheric temperature (room temperature) without the heating. In this case, the manufacturing steps can be simplified.

<Effect of First Embodiment>

Next, an effect of the present first embodiment will be explained.

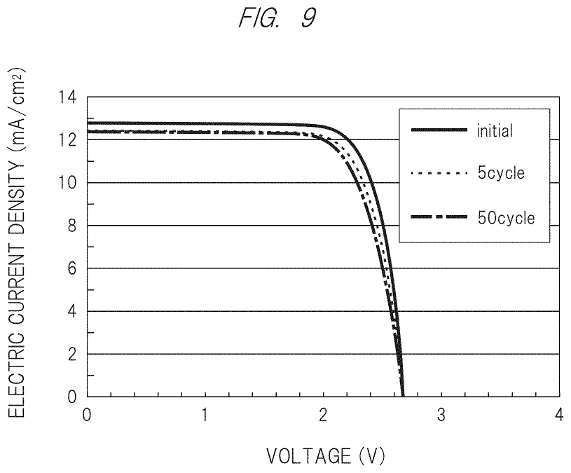

FIG. 9 is a graph showing a result of the reliability test (the temperature cycle test) on the multi-junction solar battery of the present first embodiment. Specifically, FIG. 9 shows current-voltage characteristics of the multi-junction solar battery provided before and after the temperature cycle test. In FIG. 9, a vertical axis indicates an electric current density (mA/cm²) while a horizontal axis indicates a voltage (V). In FIG. 9, a solid-line graph (“initial”) is a graph showing the current-voltage characteristics provided before the temperature cycle test. From the solid-line graph shown in FIG. 9, it is found that the multi-junction solar battery of the first embodiment has a short-circuit current of 12.76 (mA/cm²), an open-circuit voltage of 2.68 (V), a fill factor of 0.77 and a power generation efficiency of 26.32%.

On the other hand, in FIG. 9, a dashed-line graph is a graph showing the current-voltage characteristics provided after the temperature cycle test of 5 cycles, and a dashed-dotted-line graph is a graph showing the current-voltage characteristics provided after the temperature cycle test of 50 cycles.

In this case, the temperature cycle test of 50 cycles, one of which is temperature change from −40° C. to +85° C., were performed.

First, even after the temperature cycle test of 50 cycles, the multi-junction solar battery of the present first embodiment did not receive a physical damage as typified by the peeling of the junction layer 120. In other words, this result of the temperature cycle test confirms that the reliability of the mechanical junction of the junction layer 120 in the multi-junction solar battery of the first embodiment can be improved by arranging not only the plurality of conductive nanoparticles 105 but also the adhesive material 116 filling the gaps among the plurality of conductive nanoparticles in the junction layer 120.

Further, as shown in FIG. 9, it is found that I-V characteristics does not significantly change before and after the temperature cycle test. Specifically, if attention is paid to, for example, the power generation efficiency, the power generation efficiency before the temperature cycle test is 26.32% while the power generation efficiency after the temperature cycle test (of 50 cycles) is 24.32%, and a deterioration rate of the power generation efficiency is equal to or smaller than 10% even if there is a measurement error.

As described above, in the multi-junction solar battery of the present first embodiment, the significant effect that can sufficiently improve the reliability of the mechanical junction of the junction layer 120 can be provided while the reduction in the performance of the solar battery due to the temperature cycle is minimized.

<Discussion on Influence of Adhesive Material on Junction Quality>

Subsequently, influence of the addition of the adhesive material 116 will be explained.

In this case, the junction quality of the junction layer 120 can be discussed in terms of junction resistance and light loss.

First, the junction resistance of the junction interface will be discussed.

The junction resistance can be calculated from a gradient of the current-voltage characteristics (I-V characteristics). Regarding this point, because of the calculation of the junction resistance from the gradient of the I-V characteristics, it is already known that the junction resistance of the multi-junction solar battery of the “smart stacking technique” is 1 Ωcm².

On the other hand, the junction resistance of the multi-junction solar battery of the present first embodiment is calculated from the gradient of the I-V characteristics shown in FIG. 9. Specifically, the junction resistance is estimated, based on a gradient of vicinity of the open-circuit voltage of the I-V characteristics shown in FIG. 9. A differential resistance provided from the gradient of the I-V characteristics is an entire element resistance. In other words, the differential resistance provided from the gradient of the I-V characteristics has a combination value of an electrode resistance, an element resistance and a junction resistance. In this case, the differential resistance of the multi-junction solar battery of the “smart stacking technique” is 18 Ωcm². On the other hand, the differential resistance of the multi-junction solar battery of the present first embodiment is 15 Ωcm². Since there is no much difference in the electrode resistance and the element resistance between the multi-junction solar battery of the “smart stacking technique” and the multi-junction solar battery of the present first embodiment, the junction resistance of the multi-junction solar battery of the present first embodiment is about 1 Ωcm², and can be estimated to be equal to the junction resistance of the multi-junction solar battery of the “smart stacking technique”. Therefore, it is concluded that even the usage of the adhesive material 116 does not significantly affect the junction resistance of the junction layer 120.

Next, the light loss of the junction interface will be discussed.

The light loss of the junction interface includes absorbent loss and reflection loss.

In this case, the light loss of the junction interface of the multi-junction solar battery of the “smart stacking technique” is about 3% as an evaluation result of the transmissivity characteristics of its sample and an estimated result based on the calculation using the FDTD method. On the other hand, the light loss of the multi-junction solar battery of the present first embodiment is estimated from, for example, quantum efficiency characteristics. In other words, the light loss of the junction interface is estimated, based on a measurement result of a photocurrent sensitivity of each of cells (a top cell, a middle cell and a bottom cell) to a wavelength, the cells configuring the multi-junction solar battery of the present first embodiment. As a result, the light loss of the junction interface even in the multi-junction solar battery of the present first embodiment is estimated to be about the same as that in the multi-junction solar battery of the “smart stacking technique”. Therefore, it can be concluded that the absorbent loss due to the adhesive material 116 is ignorable while the reflection loss due to the adhesive material 116 is not different from that of the multi-junction solar battery of the “smart stacking technique”.

As described above, in the multi-junction solar battery of the present first embodiment, the reliability of the mechanical junction of the junction layer 120 can be improved more than that of the multi-junction solar battery of the “smart stacking technique”, and the same junction quality as that of the multi-junction solar battery of the “smart stacking technique” can be also maintained.

### Second Embodiment

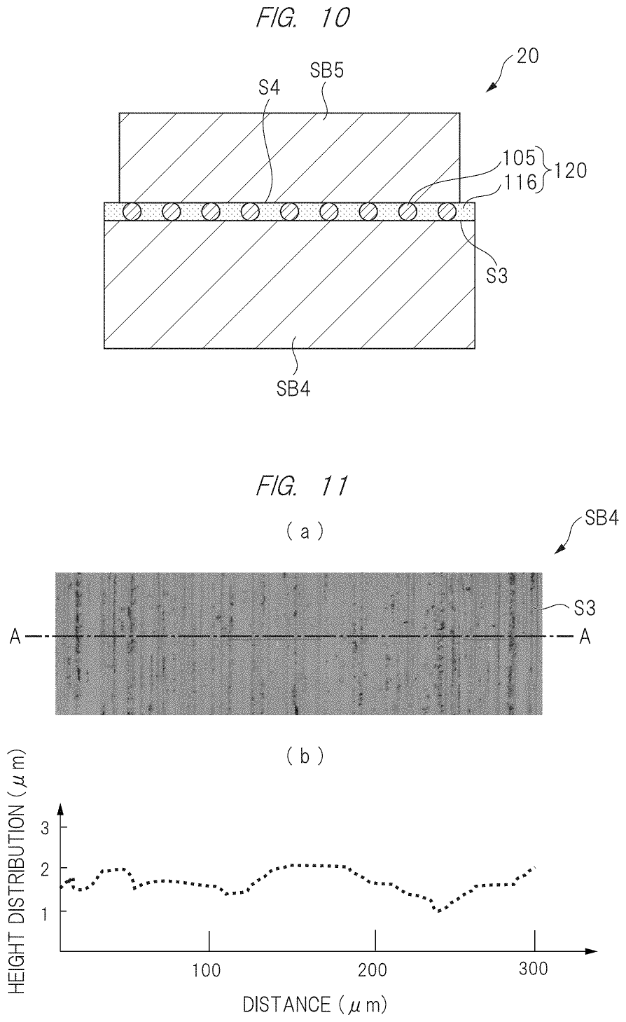

FIG. 10 is a diagram showing a schematic configuration of a solar battery according to the present second embodiment.

In FIG. 10, the solar battery 20 according to the present second embodiment includes a solar battery element SB4 and a solar battery element SB5. In this case, the solar battery element SB4 is made of a silicon cell while the solar battery element SB5 is made of a GaAs cell. In the solar battery 20 according to the present second embodiment, the solar battery element SB5 is stacked on the solar battery element SB4 through a junction layer 120. In other words, an interface S3 of the solar battery element SB4 and an interface S4 of the solar battery element SB5 are joined to each other by the junction layer 120. In this case, the junction layer 120 is made of the plurality of orderly-arranged conductive nanoparticles 105 and the adhesive material 116 filling the gaps among the plurality of conductive nanoparticles 105. Note that the interface S3 of the solar battery element SB4 made of, for example, the silicon cell has the large concavity/convexity of the surface roughness because of not having underwent the chemical mechanical polishing (CMP).

Specifically, FIG. 11(a) shows an image provided from observation of the interface S3 of the solar battery element SB4 made of the silicon cell by a stereomicroscope. Meanwhile, FIG. 11(b) shows a graph showing a result provided from measurement of a height profile on a line A-A shown in the image of FIG. 11(a) by a laser microscope.

As shown in FIG. 11(a), it is found that the interface S3 of the solar battery element SB4 made of the silicon cell has a cutting scratch. As shown in FIG. 11(b), the interface S3 of the solar battery element SB4 made of the silicon cell has the large surface roughness of about 1 μm.

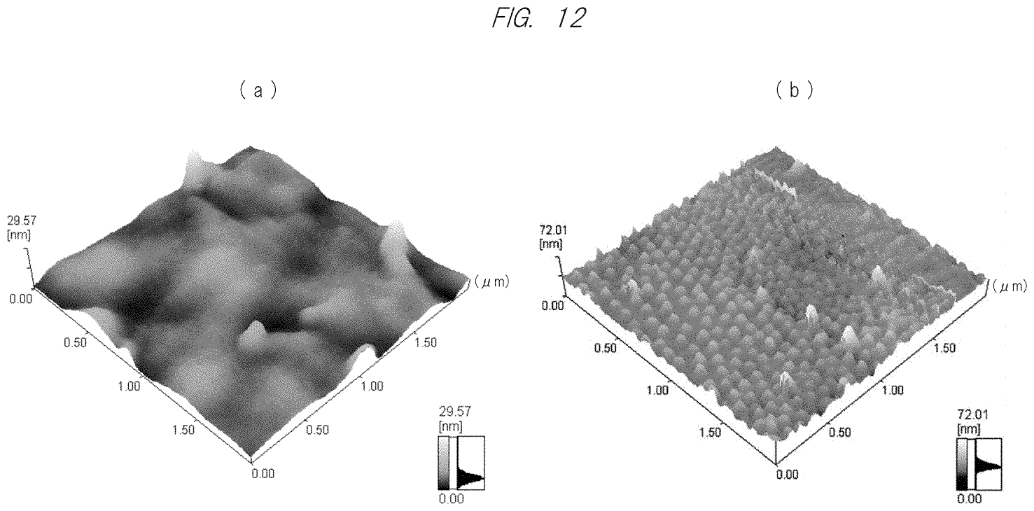

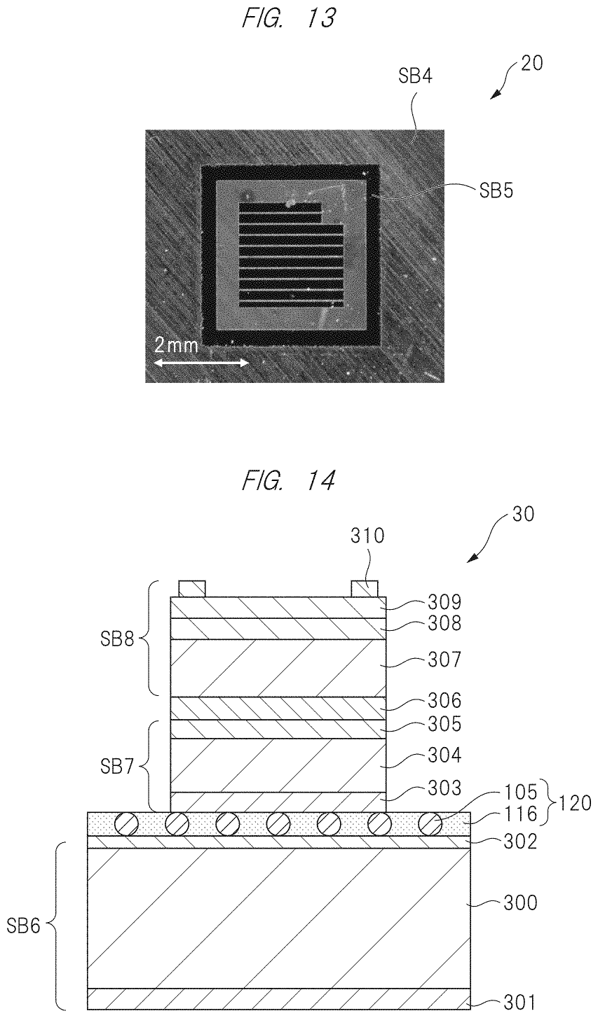

FIG. 12(a) shows a result provided from observation of the concavity/convexity formed in a micro region (μm×μm) of the interface (S3) of the solar battery element (SB4) by an atomic force microscope. As shown in FIG. 12(a), a root mean square roughness is microscopically about 15 nm. Meanwhile, FIG. 12(b) shows a result provided from observation of the arrangement state of the conductive nanoparticles in the micro region (μm×μm) of the interface (S3) of the solar battery element (SB4) by an atomic force microscope. As shown in FIG. 12(b), it is found that a part of the micro region has a protrusion caused by anomalous precipitation of the conductive nanoparticles due to the concavity/convexity of the interface (S3). Even in the solar battery element (SB4) including the interface (S3) having the large surface roughness and the microscopic concavity/convexity formed thereon as describe above, the reliability of the junction between the solar battery element SB4 and the solar battery element SB5 can be secured by the usage of the junction layer (120) made of the plurality of orderly-arranged conductive nanoparticles (105) and the adhesive material (116) filling the gaps among the plurality of conductive nanoparticles (105). FIG. 13 shows an outer appearance picture of the solar battery 20 in which the solar battery element SB5 is stacked on the solar battery element SB4 along with the usage of the junction layer (120) made of the plurality of orderly-arranged conductive nanoparticles (105) and the adhesive material (116) filling the gaps among the plurality of conductive nanoparticles (105). As shown in FIG. 13, it is found that the solar battery element SB4 and the solar battery element SB5 configuring the solar battery 20 can be reliably joined to each other.

### Third Embodiment

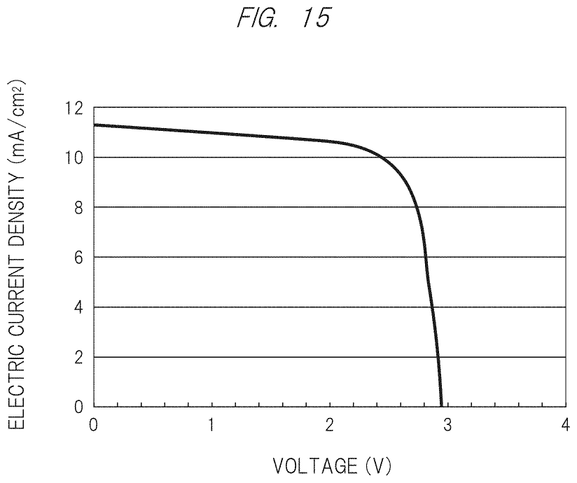

FIG. 14 is a diagram showing a schematic configuration of a solar battery according to the present third embodiment.

In FIG. 14, the solar battery 30 according to the present third embodiment includes a solar battery element SB6, a solar battery element SB7 and a solar battery element SB8. In this case, the solar battery element SB6 is made of a silicon cell. On the other hand, the solar battery element SB7 is made of an AlGaAs cell, and the solar battery element SB8 is made of an InGaP cell.

The solar battery element SB6 includes, for example, a p-type silicon substrate 300 on which a p-type electrode 301 made of aluminium is formed and an n-type silicon layer 302 formed on the p-type silicon substrate 300. The solar battery element SB6 is formed as described above.

Next, the solar battery element SB7 includes a p-type GaAs layer 303 functioning as a buffer layer, a p-type AlGaAs layer 304 functioning as a light absorbent layer formed on the p-type GaAs layer 303, and an n-type GaAs layer 305 formed on the p-type AlGaAs layer 304. The solar battery element SB7 is formed as described above.

Next, the solar battery element SB8 includes a p-type InGaP layer 307, an n-type InGaP layer 308 formed on the p-type InGaP layer 307, an n-type InAlP layer 309 formed on the n-type InGaP layer 308, and an n-type electrode 310 formed on the n-type InAlP layer 309. The solar battery element SB8 is formed as described above.

In this case, the solar battery element SB7 and the solar battery element SB8 are formed on one semiconductor chip. In other words, the solar battery element SB7 and the solar battery element SB8 are joined and are electrically connected in series to each other by a tunnel junction 306 formed in the semiconductor chip. For example, the tunnel junction 306 is made of a degenerate semiconductor layer. Therefore, the n-type GaAs layer 305 of the solar battery element SB7 and the p-type InGaP layer 307 of the solar battery element SB8 are electrically connected to each other. The solar battery element SB7 and the solar battery element SB8 are sequentially epitaxially grown on the GaAs substrate as similar to the solar battery element SB2 and the solar battery element SB3 of the above-described first embodiment, and then, are separated from the GaAs substrate by using the ELO method.

On the other hand, the solar battery element SB6 is significantly different in the crystal structure from the solar battery element SB7 and the solar battery element SB8, and therefore, the solar battery element SB6 is formed on a third semiconductor chip that is different from a fourth semiconductor chip on which the solar battery element SB7 and the solar battery element SB8 are formed. A surface of the solar battery element SB6 has the large concavity/convexity as similar to the structure of the solar battery element SB4 (silicon solar battery element) of the above-described second embodiment.

As shown in FIG. 14, the third semiconductor chip on which the solar battery element SB6 is formed and the fourth semiconductor chip on which the solar battery element SB7 and the solar battery element SB8 are formed are joined to each other by, for example, the junction layer 120 containing the plurality of conductive nanoparticles 105 and the adhesive material 116. In this manner, the third semiconductor chip on which the solar battery element SB6 is formed and the fourth semiconductor chip on which the solar battery element SB7 and the solar battery element SB8 are formed are mechanically joined and electrically connected to each other. For example, as the conductive nanoparticle 105, a nanoparticle made of palladium (Pd) can be used.

Even in the solar battery 30 of the present third embodiment configured as described above, the reliability of the junction between the solar battery element SB6 and the solar battery element SB7 can be secured by the usage of the junction layer 120 containing the plurality of orderly-arranged conductive nanoparticles 105 and the adhesive material 116 filling the gaps among the plurality of conductive nanoparticles 105.

FIG. 15 is a graph showing a power generation performance (current-voltage characteristics) of the solar battery of the present third embodiment. In FIG. 15, a vertical axis indicates an electric current density (mA/cm²) while a horizontal axis indicates a voltage (V). From the graph shown in FIG. 15, it is found that the solar battery of the present third embodiment has a short-circuit current of 11.25 (mA/cm²), an open-circuit voltage of 2.95 (V), a fill factor of 0.74 and a power generation efficiency of 24.66%.

Therefore, it is found that the solar battery of the present third embodiment can provide the significant effect capable of sufficiently improving the reliability of the mechanical junction of the junction layer 120 while exerting the solar battery performance at an acceptable level.

In the foregoing, the invention made by the present inventors has been concretely described on the basis of the embodiments. However, it is needless to say that the present invention is not limited to the foregoing embodiments, and various modifications can be made within the scope of the present invention.

For example, the technical concept of the embodiments are widely applicable even when a crystal silicon-based material, an amorphous silicon material, a microcrystal silicon-based material, a group III-V element semiconductor material, a group II-VI element semiconductor material, a germanium material, an organic semiconductor material, a perovskite-based material, a chalcopyrite-based material or a chalcogenide-based material is used as the materials of the first semiconductor element and the second semiconductor element that are joined to each other.

While the present disclosure has been illustrated and described with respect to a particular embodiment thereof, it should be appreciated by those of ordinary skill in the art that various modifications to this disclosure may be made without departing from the spirit and scope of the present disclosure.

1. A semiconductor device comprising:
a first semiconductor element including a first junction surface;
a second semiconductor element including a second junction surface facing the first junction surface; and
a junction layer being in contact with the first junction surface and the second junction surface and having light transmissivity,
wherein the junction layer includes:
a plurality of conductive nanoparticles electrically connecting the first semiconductor element and the second semiconductor element; and
an adhesive material filling gaps among the plurality of conductive nanoparticles, the first junction surface includes:
a flat surface having concavity/convexity that is equal to or smaller than 2/3 times the minimum thickness of the junction layer; and
a concave portion having a depth that is equal to or larger than twice the minimum thickness of the junction layer with respect to the flat surface.

2. The semiconductor device according to claim 1,
wherein the plurality of conductive nanoparticles are orderly arranged, and
each of the plurality of conductive nanoparticles contains any of palladium, gold, silver, platinum, nickel, aluminium, indium, indium oxide, zinc, zinc oxide and copper.

3. The semiconductor device according to claim 1,
wherein the plurality of conductive nanoparticles include:
a first conductive nanoparticle interposing between the first junction surface and the second junction surface and contributing to electrical connection between the first junction surface and the second junction surface; and
a second conductive nanoparticle interposing between the first junction surface and the second junction surface but not contributing to the electrical connection between the first junction surface and the second junction surface.

4. The semiconductor device according to claim 3,
wherein the first conductive nanoparticle and the second conductive nanoparticle are different in a shape from each other, and
a height of the first conductive nanoparticle is smaller than a height of the second conductive nanoparticle.

5. The semiconductor device according to claim 1,
wherein the first semiconductor element is a first solar battery cell capable of absorbing light having a first wavelength band, and
the second semiconductor element is a second solar battery cell capable of absorbing light having a second wavelength band shorter than the first wavelength band.

6. The semiconductor device according to claim 5,
wherein the first solar battery cell is a polycrystalline cell, and
the second solar battery cell is a monocrystalline cell.

7. A method of manufacturing a semiconductor device comprising the steps of:
(a) preparing a first semiconductor element including a first junction surface;
(b) preparing a second semiconductor element including a second junction surface;
(c) arranging a plurality of conductive nanoparticles on the first junction surface,
(d) after the step (c), applying an adhesive material to the first junction surface; and
(e) after the step (d), pressing the second junction surface to the first junction surface to face each other through the plurality of conductive nanoparticles and the adhesive material.

8. The method of manufacturing the semiconductor device according to claim 7,
wherein the step (e) is performed without heating.
